(19) United States
(12) Patent Application Publication
(10) Pub. No.: US 2009/0001544 A1
(43) Pub. Date: Jan. 1, 2009

(54) CHIP STACKED STRUCTURE AND METHOD OF FABRICATING THE SAME

(76) Inventor: Chung-Kyung Jung, Anyang-si (KR)

Correspondence Address: SHERR & VAUGHN, PLLC, 620 HERNDON PARKWAY, SUITE 200, HERNDON, VA, 20170, US

(21) Appl. No.: 12/141,268

(22) Filed: Jun. 18, 2008

(30) Foreign Application Priority Data
Jun. 29, 2007 (KR) 10-2007-0065058

(51) Int. Cl. H01L 23/48; H01L 21/00

(52) U.S. Cl. 257/686; 257/777; 438/109; 257/E23.141; 257/E21.001

(57) ABSTRACT

A chip stacked structure and a method of fabrication the same that may include a first chip having first semiconductor devices and a first connection pad electrically connected to the first semiconductor devices, a second chip stacked on the first chip, the second chip having second semiconductor devices and a second connection pad electrically connected to the second semiconductor devices, and a connection member interposed between the first connection pad and the second connection pad to electrically connect the first connection pad and the second connection pad. The connection member has lower electric resistance than when the chips are unstacked, and thus, offers high reliability and performance.

The present application claims priority under 35 U.S.C. §119 to Korean Patent Application No. 10-2007-0065058 (filed on Jun. 29, 2007), which is hereby incorporated by reference in its entirety.

### BACKGROUND

The modern market for portable electronic products has experienced significant growth. In order to satisfy such growth, it is essential to make highly integrated components (i.e., thin, short and small) for mounting on and/or over a system. In order to achieve such size requirements in components, technology for reducing an individual size of a semiconductor package being a mounted component may use a system-on-chip (SOC) method of making a plurality of individual semiconductor chips into a single chip, and a system-in-package method of integrating a plurality of semiconductor chips into a single package.

### SUMMARY

Embodiments relate to a chip stacked structure and a method of fabricating the same, which has enhanced adhesion between chips and increased yield and reliability.

Embodiments relate to a chip stacked structure that can include at least one of the following: a first chip including first semiconductor devices and a first connection pad electrically connected to the first semiconductor devices; a second chip stacked on and/or over the first chip, including second semiconductor devices and a second connection pad electrically connected to the second semiconductor devices and facing the first connection pad; and a connection member interposed between the first connection pad and the second connection pad to electrically connect the first connection pad and the second connection pad.

Embodiments relate to a method of fabrication a chip stacked structure that can include at least one of the following steps: disposing a connection member electrically connected to a first connection pad on and/or over a first chip including first semiconductor devices, the first connection pad being electrically connected to the first semiconductor devices; and then forming anti-oxidation layers on and/or over surfaces of the first chip and the connection member; and then removing the anti-oxidation layers; and then disposing the first chip and the connection member on and/or over a second chip including second semiconductor devices and a second connection pad electrically connected to the second semiconductor devices and electrically connecting the second connection pad and the connection pad.

Embodiments relate to a method of fabrication a chip stacked structure that can include at least one of the following steps: forming a first chip having a first connection pad and first semiconductor devices electrically connected to first connection pad; and then disposing a connection member on an exposed end of the first connection pad and electrically connected to the first connection pad; and then forming an anti-oxidation layer on exposed surfaces of the first chip and the connection member; and then forming a second chip having a second connection pad and second semiconductor devices electrically connected to the second connection pad; and then manipulating at least one of the first chip and the second chip such that an exposed surface of the connection member faces the second connection pad; and then removing the anti-oxidation layer; and then electrically connecting the first chip to the second chip by connecting the connection member to the second connection pad.

Embodiments relate to a method that can include at least one of the following steps: providing a first chip having a first connection pad electrically connected to first semiconductor devices formed on the first chip and a second chip having a second connection pad electrically connected to second semiconductor devices formed on the second chip; and then disposing a connection member on and electrically connected to the first connection pad; and then forming an anti-oxidation layer on exposed surfaces of the first chip and the connection member; and then removing the anti-oxidation layer by exposing the anti-oxidationlayer to a solvent mixuture; and then electrically connecting the first chip to the second chip by connecting the connection member to the second connection pad.

### DRAWINGS

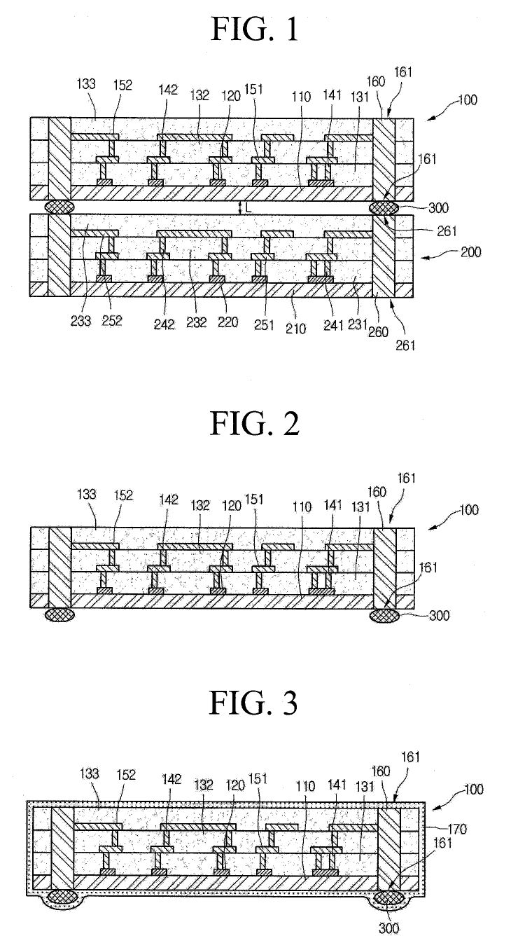

Example FIGS. 1 to 5 illustrate a chip stacked structure and a method of fabrication a chip stacked structure in accordance with embodiments.

### DESCRIPTION

As illustrated in example FIG. 1, a chip stacked structure may include first chip 100, second chip 200 and connection member 300 interposed between first chip 100 and second chip 200 and for connected first chip 100 to second chip 200. First chip 100 may include first silicon wafer 110, first semiconductor devices 120, first dielectric layer 131, first vertical interconnections 141, first horizontal interconnections 151, second dielectric layer 132, second vertical interconnections 142, second horizontal interconnections 152, third dielectric layer 133, first through electrode 160 and first connection pad 161. As an example of materials used for first silicon wafer 110, there may be single crystal silicon, etc. First silicon wafer 110 may have, for example, a plate shape.

A plurality of first semiconductor devices 120 may be formed spaced apart on and/or over first silicon wafer 110. First semiconductor devices 120 may be, for example, a CMOS transistor, a double diffused MOS (DMOS) transistor, a transistor, a capacitor, and a bipolar-junction transistor. First dielectrice film 131 may be formed on and/or over first silicon wafer 110 and covers first semiconductor devices 120. First vertical interconnections 141 may be formed penetrating through first dielectric layer 131 and are electrically connected to first semiconductor devices 120. As an example of materials used for first vertical interconnections 141, there may be metals such as copper (Cu), aluminum (Al), titanium (Ti), tungsten (W) and iron (Fe), etc. First horizontal interconnections 151 may be formed on and/or over first dielectric layer 131 and are electrically connected to first vertical interconnections 141. As an example of materials used for the first horizontal interconnections 151, there may be metals such as copper (Cu), aluminum (Al), titanium (Ti), tungsten (W) and iron (Fe), etc.

Second dielectric layer 132 may be formed on and/or over first dielectric layer 131 and covers first horizontal interconnections 151. Second vertical interconnections 142 may be formed penetrating through second dielectric layer 132 and are electrically connected to second horizontal interconnections 152. Second horizontal interconnections 152 may be formed on and/or over second dielectric layer 132 and are electrically connected to second vertical interconnections 142. Third dielectric layer 133 may be formed on and/or over second dielectric layer 132 and covers second horizontal interconnections 152.

First through electrode 160 may be formed penetrating through first silicon wafer 110, first dielectric layer 131, second dielectric layer 132 and third dielectric layer 133. As an example of materials used for first through electrode 160, there may be metals such as copper, tungsten, and aluminum, etc. Alternatively, first through electrode 160 may be formed penetrating through a portion of first chip 100. For example, first through electrode may be formed penetrating through a portion of first silicon wafer 110, first dielectric layer 131 and second dielectric layer 132.

First connection pad 161 may be provided on and/or over one end or both exposed ends of first through electrode 160. First semiconductor devices 120 may be electrically connected to first connection pad 161 by first vertical interconnections 141, first horizontal interconnections 151, second vertical interconnections 142, second horizontal interconnections 152 and first through electrode 160. Therefore, signals applied from an external device(s) through first connection pad 161 may be applied to first semiconductor devices 120. In turn, signals stored in first semiconductor devices 120 may be applied to the external device(s) through first connection pad 161. Alternatively, first connection pad 161 may be electrically connected to first through electrode 160 and may be formed on and/or over first chip 100. First connection pad 161 may be electrically connected to first through electrode 160 so that it is electrically connected to first semiconductor devices 120.

Second chip 200 may be spatially disposed having an exposed surface spaced apart predetermined interval L from an exposed surface of first chip 100. Interval L may be in a range between about 4 to 6 μm. Second chip 200 may be spatially disposed so that first connection pad 161 and second connection pad 261 of second chip 200 face each other. Second chip 200 may include second silicon wafer 210, second semiconductor devices 220, fourth dielectric layer 231, third vertical interconnections 241, third horizontal interconnections 251, fifth dielectric layer 232, fourth vertical interconnections 242, fourth horizontal interconnections 252, sixth dielectric layer 233, second through electrode 260 and second connection pad 261. As an example of materials used for second silicon wafer 210, there may be single crystal silicon, etc. Second silicon wafer 210 may have, for example, a plate shape.

A plurality of second semiconductor devices 220 may be formed on and/or over second silicon wafer 210. Second semiconductor devices 220 may be, for example, a CMOS transistor, a double diffused MOS (DMOS) transistor, a transistor, a capacitor, and a bipolar-junction transistor. Fourth dielectrice film 231 may be formed on and/or over first silicon wafer 210 and covers first semiconductor devices 220. Third vertical interconnections 241 may be formed penetrating through fourth dielectric layer 231 and are electrically connected to second semiconductor devices 220. As an example of materials used for third vertical interconnections 241, there may be a metal such as copper (Cu), aluminum (Al), titanium (Ti), tungsten (W) and iron (Fe), etc. Third horizontal interconnections 251 may be formed on and/or over fourth dielectric layer 231 and are electrically connected to third vertical interconnections 241. As an example of materials used for third horizontal interconnections 251, there may be a metal such as copper (Cu), aluminum (Al), titanium Ti, tungsten W, and iron Fe, etc.

Fifth dielectric layer 232 may be formed on and/or over fourth dielectric layer 231 and covers third horizontal interconnections 251. Fourth vertical interconnections 242 may be formed penetrating through fifth dielectric layer 232 and are electrically connected to third horizontal interconnections 251. Fourth horizontal interconnections 252 may be formed penetrating through fifth dielectric layer 232 and are electrically connected to fourth vertical interconnections 242.

Sixth dielectric layer 233 may be formed on and/or over fifth dielectric layer 232 and covers fourth horizontal interconnections 252. Second through electrode 160 may be formed penetrating through second silicon wafer 210, fourth dielectric layer 231, fifth dielectric layer 232 and sixth dielectric layer 233. As an example of materials used for second through electrode 260, there may be metals such as copper, tungsten, and aluminum, etc. Alternatively, second through electrode 260 may be formed penetrating through a portion of second chip 200. For example, second through electrode 260 may be formed penetrating through a portion of second silicon wafer 210, fourth dielectric layer 231 and fifth dielectric layer 232.

Second connection pad 261 may be provided one and/or over one or both exposed ends of second through electrode 260. Second semiconductor devices 220 may be electrically connected to second connection pad 261 by third vertical interconnections 241, third horizontal interconnections 251, fourth vertical interconnections 242, fourth horizontal interconnections 252 and second through electrode 260. Therefore, signals applied from an external device(s) through second connection pad 261 may be applied to second semiconductor devices 220. In turn, signals stored in second semiconductor devices 220 may be applied to the external device(s) through second connection pad 261. Alternatively, second connection pad 261 may be electrically connected to second through electrode 260 and may be formed on and/or over second chip 100. Second connection pad 261 may be electrically connected to second through electrode 260 so that it is electrically connected to second semiconductor devices 220.

Connection members 300 may be interposed between first chip 100 and second chip 200. Connection members 300 may be interposed between first connection pad 161 and second connection pad 261 to contact first connection pad 161 and second connection pad 261. Connection members 300 may be electrically connected to first connection pad 161 and second connection pad 261. Connection member 300 may have, for example, a column (rectangular) shape or a ball (circular) shape. Connection member 300 may have a column shape having a height in a range of between about 4 to 6 μm. Connection member 300 may have a ball shape having a diameter in a range of between about 4 to 6 μm in diameter. Connection member 300 may be solder paste having a thickness in a range of between about 4 to 6 μm.

First chip 100, second chip 200 and connection members 300 may be connected to each other by a fixing member disposed on and/or over an outermost surface of first chip 100 and second chip 200 and/or adhesives interposed between first chip 100 and second chip 200.

The above-mentioned chip stacked structure in accordance with embodiments illustrated in example FIG. 1 may have a chip stacked in two layers. However, embodiments are not limited thereto. For example, the chip stacked structure may have a plurality of chips stacked in more than three layers. In this case, more than three chips may be stacked in the same form as chips 100 and 200 illustrated in example FIG. 1 and described herein.

Example FIGS. 2 to 5 illustrate a method of fabrication a chip stacked structure in accordance with embodiments.

As illustrated in example FIG. 2, first chip 100 may be formed and connection member 300 may be disposed on and/or over connection pad 161. In order to form first chip 100, first semiconductor devices 120 are formed on and/or over first silicon wafer 110. First dielectric layer 131 may then be formed on and/or over first silicon wafer 110 including first semiconductor devices 120. First dielectric layer 131 may then be etched by a mask process to form a plurality of first via holes exposing first semiconductor devices 120. The first via holes may then be filled with a metal material to form first vertical interconnections 141. After first vertical interconnections 141 are formed, a metal layer covering first dielectric layer 131 may then be formed. The metal layer may then be patterned by a mask process to form first horizontal interconnections 151. After first horizontal interconnections 151 are formed, second dielectric layer 132 covering first horizontal interconnections 151 may then be formed on and/or over first dielectric layer 131. Second dielectric layer 132 may then be etched by a mask process to form a plurality of second via holes exposing first horizontal interconnections 151. The second via holes may then be filled with a metal material to form second vertical interconnections 142.

After second vertical interconnections 142 are formed, a metal layer covering second dielectric layer 132 may then be formed. The metal layer may then be patterned by a mask process to form second horizontal interconnections 152. After second horizontal interconnections 152 are formed, third dielectric layer 133 covering second horizontal interconnections 152 may then be formed on and/or over second dielectric layer 132. After third dielectric layer 133 is formed, a third via hole may then be formed penetrating through at least a portion of first silicon wafer 110, first dielectric layer 131, second dielectric layer 132 and third dielectric layer 133. The third via hole may then be filled with a metal material. First silicon wafer 110 may then be cut in a horizontal direction to form first through electrode 160. At this time, both ends of first through electrode 160 are exposed such that the exposed ends forms first connection pad 161. As an example of materials used as the metal, there may be a metal such as copper, tungsten, and aluminum, etc. First through electrode 160 may be formed to electrically connect to at least a portion of second horizontal interconnections 152.

After first chip 100 is formed, connection member 300 may then be disposed on and/or over an exposed end of through electrode 160. Connection member 300 may be composed of a conductive material such as a metal. An example of materials used for connection member 300 may be copper, aluminum, silver, zinc, gold, titanium, tungsten, and molybdenum (Mo), etc. Connection member 300 may have a column shape, a ball shape or a solder paste shape. Connection member 300 may have a column shape of between about 4 to 6 μm in height or a ball shape of between about 4 to 6 μm in diameter. Connection member 300 may be a solder paste of between 4 to 6 μm in thickness.

As illustrated in example FIG. 3, after connection member 300 is disposed on and/or over first connection pad 161, anti-oxidation layer 170 may then be formed on and/or over exposed surfaces of first chip 100 and connection member 300. Anti-oxidation layer 170 may be formed by depositing an anti-oxidation material on and/or over exposed surfaces of first chip 100 and connection member 300 by plasma enhanced chemical vaporation deposition (PECVD) that is performed for between 5 to 10 minutes at a temperature range of between about 50 to 200° C. under a pressurerange of between about 10 to 50 Mtorr. Anti-oxidation layer 170 may be composed of a polymeric material. Anti-oxidation layer 170 may be composed of a material such as at least one of cyclohexane based resin, acrylic based resin, polyimide, benzocyclobutene, polybenzoxazol, epoxy resin and a phenol based resin.

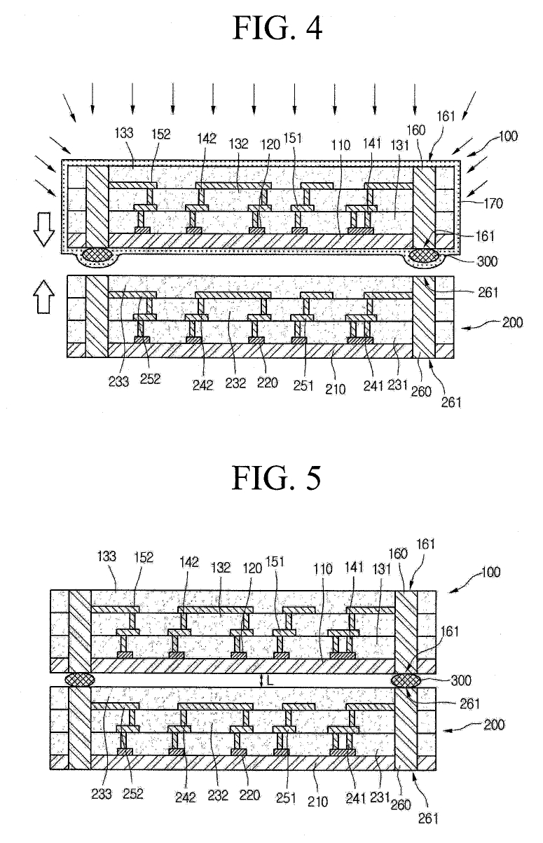

As illustrated in example FIG. 4, second chip 200 may then be formed. In order to form second chip 200, second semiconductor devices 200 may be formed on and/or over second silicon wafer 210. Fourth dielectric layer 231 may then be formed on and/or over second silicon wafer 210 including second semiconductor devices 220. Fourth dielectric 231 may then be etched by a mask process to form a plurality of fourth via holes exposing second semiconductor devices 220. The fourth via holes may then be filled with a metal material to form third vertical interconnections 241. After third vertical interconnections 241 are formed, a metal layer covering fourth dielectric layer 231 may then be formed. The metal layer may then be patterned by a mask process to form third horizontal interconnections 251. After third horizontal interconnections 251 are formed, fifth dielectric layer 232 covering third horizontal interconnections 251 may then be formed on and/or over fourth dielectric layer 231. Fifth dielectric layer 232 may then be etched by a mask process to form a plurality fifth via holes exposing third horizontal interconnections 251. The fifth via holes may then be filled with a metal material to form fourth vertical interconnections 242.

After fourth vertical interconnections 242 are formed, a metal layer covering fifth dielectric layer 232 may then be formed. The metal layer may then be patterned by a mask process to form fourth horizontal interconnections 252. After fourth horizontal interconnections 252 are formed, sixth dielectric layer 233 covering fourth horizontal interconnections 252 may then be formed on and/or over fifth dielectric layer 232. After sixth dielectric layer 233 is formed, a sixth via hole may then be formed penetrating through at least a portion of second silicon wafer 210, fourth dielectric layer 231, fifth dielectric layer 232 and sixth dielectric layer 233. The sixth via hole may then be filled with a metal material. Second silicon wafer 210 may then be cut in a horizontal direction to form second through electrode 260. Both ends of second through electrode 260 may then be exposed such that the exposed ends may form second connection pad 261. As an example of materials used as the metal, there may be copper, tungsten, and aluminum, etc. Second through electrode 260 may be formed to electrically connect to at least a portion of fourth horizontal interconnections 252.

After second chip 200 is formed, connection member 300 and second connection pad 261 may then be diposed to face each other. Thereafter, anti-oxidation layer remover may then be sprayed to remove anti-oxidation layer 170. The anti-oxidation layer remover may include, for example, at least one of tetramethylhydroxide (TMH), hydrogen peroxide and water. The anti-oxidation layer remover may include at least one of TMH at a concentration in a range between about 2.0 to 3.0 mol %, hydrogen peroxide in a range between of about 5.0 to 6.0 mol % and water in a range between of about 91.0 to 93.0 mol %. The anti-oxidation layer remover may alternatively include at least one of ammonium fluoride (NH₄F), boron hydro fluoride (BHF), hydrogen peroxide and water. The anti-oxidation layer remover may alternatively include at least one of sulfuric acid and water. The anti-oxidation layer remover may be sprayed on and/or over first chip 100 and second connection member 300 to remove anti-oxidation layer 170. The anti-oxidation layer remover simultaneously removes foreign materials from the surfaces of first chip 100 and connection member 300. The anti-oxidation layer remover may also simultaneously react with portions projected from the surface of first silicon wafer 110 and surface of the metals in order to remove the projected portions. In other words, the anti-oxidation layer remover may serve to also reduce the surface roughness of first chip 100 and connection member 300.

First chip 100 and second chip 200 may then be manipulated in order to contact connection member 300 to second connection pad 261. Therefore, first through electrode 160 and second through electrode 260 are electrically connected by connection member 300.

The chip stacked structure in accordance with embodiments disposes the chips to allow connection pads to face each other and interposes a connection member electrically connecting the upper and lower chips between the connection pads. Therefore, the connection member has a cross section wider than a plane of the connection pad and has a length equal to a spatial interval between the chips. Therefore, the connection member in accordance with embodiments may have a lower electric resistance than when the chips are not stacked or the connection pads are not faced with each other. Since the electric resistance is low, the chip stacked structure in accordance with embodiments may have high reliability and performance. Also, the chips may be stacked so that they are strong against physical impact from the outside than when the chips are disposed horizontally.

The method of fabrication the chip stacked structure in accordance with embodiments may form an anti-oxidation layer on the surfaces of a chip and also the connection member. The anti-oxidation layer may serve to prevent the oxidation of metals of the chip and the connection member during the fabrication process. Therefore, the method of fabrication a chip stacked structure can reduce the resistance of the connection member than when the anti-oxidation layer is not formed. The method in accordance with embodiments may also increase yield. An anti-oxidation layer remover may be used to remove undesirable materials from the surfaces of the chip and the connection member. The anti-oxidation layer remover may reduce the surface roughness of the chip and the connection member.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a first chip including first semiconductor devices and a first connection pad electrically connected to the first semiconductor devices;
a second chip stacked on the first chip, the second chip including second semiconductor devices and a second connection pad electrically connected to the second semiconductor devices; and
a connection member interposed between the first connection pad and the second connection pad to electrically connect the first connection pad to the second connection pad.

2. The apparatus of claim 1, wherein a spatial interval between the first chip and the second chip is in a range between 4 to 6 μm.

3. The apparatus of claim 1, further comprising a first through electrode penetrating through at least a portion of the first chip.

4. The apparatus of claim 1, further comprising a second through electrode penetrating through at least a portion of the second chip.

5. The apparatus of claim 1, wherein the connection member has a diameter in a range of between 4 to 6 μm.

6. The apparatus of claim 1, wherein the connection member has a height in a range of between 4 to 6 μm.

7. The apparatus of claim 1, wherein the connection member has a thickness in a range of between 4 to 6 μm.

8. A method comprising:
forming a first chip having a first connection pad and first semiconductor devices electrically connected to first connection pad; and then
disposing a connection member on an exposed end of the first connection pad and electrically connected to the first connection pad; and then
forming an anti-oxidation layer on exposed surfaces of the first chip and the connection member; and then
forming a second chip having a second connection pad and second semiconductor devices electrically connected to the second connection pad; and then
manipulating at least one of the first chip and the second chip such that an exposed surface of the connection member faces the second connection pad; and then
removing the anti-oxidation layer; and then
electrically connecting the first chip to the second chip by connecting the connection member to the second connection pad.

9. The method of claim 8, wherein forming the anti-oxidation layer comprises forming a polymeric material on exposed surfaces of the first chip and the connection member by a PECVD process.

10. The method of claim 9, wherein the PECVD process is performed at a temperature range of between 50 to 200° C., a pressure range of between 10 to 500 Mtorr and a time range of between 5 to 10 minutes.

11. The method of claim 10, wherein forming the anti-oxidation layer comprises forming at least one of cyclohexane based resin, acrylic based resin, polyimide, benzocyclobutene, polybenzoxazol, epoxy resin and a phenol based resin on exposed surfaces of the first chip and the connection member by a PECVD process.

12. The method of claim 12, wherein the PECVD process is performed at a temperature range of between 50 to 200° C., a pressure range of between 10 to 500 Mtorr and a time range of between 5 to 10 minutes.

13. The method of claim 10, wherein removing the anti-oxidation layer comprises exposing the anti-oxidation layer to an anti-oxidation layer removal mixture of at least one of tetramethylhydroxide, hydrogen peroxide and water.

14. The method of claim 10, wherein removing the anti-oxidation layer comprises exposing the anti-oxidation layer to an anti-oxidation layer removal mixture comprising tetramethylhydroxide at a concentration range of between 2.0 to 3.0 mol %, hydrogen peroxide at a concentration range of between 5.0 to 6.0 mol % and water at a concentration range of between 91.0 to 93.0 mol %.

15. The method of claim 10, wherein removing the anti-oxidation layer comprises exposing the anti-oxidation layer to an anti-oxidation layer removal mixture comprising at least one of sulfuric acid and water.

16. A method comprising:
providing a first chip having a first connection pad electrically connected to first semiconductor devices formed on the first chip and a second chip having a second connection pad electrically connected to second semiconductor devices formed on the second chip; and then
disposing a connection member on and electrically connected to the first connection pad; and then
forming an anti-oxidation layer on exposed surfaces of the first chip and the connection member; and then
removing the anti-oxidation layer by exposing the anti-oxidationlayer to a solvent mixuture; and then
electrically connecting the first chip to the second chip by connecting the connection member to the second connection pad.

17. The method of claim 16, wherein the solvent mixture comprises at least one of sulfuric acid and water.

18. The method of claim 16, wherein the solvent mixture comprises at least one of tetramethylhydroxide, hydrogen peroxide and water.

19. The method of claim 16, wherein the solvent mixture comprises tetramethylhydroxide at a concentration range of between 2.0 to 3.0 mol %, hydrogen peroxide at a concentration range of between 5.0 to 6.0 mol % and water at a concentration range of between 91.0 to 93.0 mol %.

20. The method of claim 16, wherein forming the anti-oxidation layer comprises forming a polymeric material on exposed surfaces of the first chip and the connection member.
